(19) United States
(12) Patent Application Publication
(10) Pub. No.: US 2005/0247554 A1
(43) Pub. Date: Nov. 10, 2005

(54) Pulsed magnetron for sputter deposition

(75) Inventors: Dinesh Saigal, San Jose, CA (US); John C. Forster, San Francisco, CA (US); Shuk Ying Lai, Campbell, CA (US)

Correspondence Address: Patent Counsel;Applied Materials, Inc., Post Office Box 450A, Santa Clara, CA, 95052, US

(73) Assignee: Applied Materials, Inc.

(21) Appl. No.: 11/064,689

(22) Filed: Feb. 23, 2005

Related U.S. Application Data
(63) Continuation of application No. 10/322,230, filed on Dec. 17, 2002, now abandoned.

(51) Int. Cl. C23C 14/32

(52) U.S. Cl. 204/192.12; 204/298.06

(57) ABSTRACT

A magnetron sputter reactor for sputtering deposition materials such as nickel and cobalt, for example, and its method of use, in which self-ionized plasma (SIP) sputtering is promoted. SIP is promoted by a small magnetron having poles of unequal magnetic strength and a high power applied to the target during sputtering. One embodiment of the present inventions is directed to sputter depositing a metal layer by biasing a sputter target with pulsed power in which the power applied to the target alternates between low and high levels. The high levels are, in one embodiment, sufficiently high to maintain a plasma for ionizing deposition material. The low levels are, in one embodiment, sufficiently low such that the power applied to the target during the high and low levels is, on average, low enough to facilitate deposition of thin layers if desired.

### FIELD OF THE INVENTION

The inventions relate generally to sputtering. In particular, the invention relates to the sputter deposition of material in the formation of semiconductor integrated circuits.

### BACKGROUND ART

Semiconductor integrated circuits such as complementary metal oxide silicon (CMOS) devices may include a silicide layer to provide low sheet resistance on gate, source or drain regions. A silicide is a compound formed in a reaction between a metal and silicon or polysilicon. In addition to CMOS, silicide can be a useful component of a variety of other semiconductor devices, particularly where a low sheet resistance or low contact resistance is desired.

Various metals may be deposited on silicon or polysilicon to react with the underlying silicon to form the silicide. Titanium is commonly reacted with silicon to form titanium silicide, TiSi₂. It has also been proposed to use cobalt and nickel to form silicides.

FIG. 1 shows a metal layer 10 which has been deposited onto a CMOS semiconductor device 12 which includes a plurality of transistor structures, an example of which is indicated generally at 14. Each transistor structure 14 includes a polysilicon gate 16 which is deposited on an insulation layer 18 overlying a silicon region 20. The gate 16 is formed in a dielectric layer 22. Each silicon region 20 is doped as appropriate to form the desired array of p-type and n-type channel transistors.

The reaction between the metal layer 10 and the polysilicon gate 16 or the silicon region 20 is often facilitated by the application of heat, either during the deposition of the metal layer 20 or after the metal deposition. FIG. 2 shows the formation of a metal silicide layer 26 on the polysilicon gate 16 and a pair of silicide layers 28 on the silicon region 20. In this example, the positions of the silicide layers 26 and 28 are aligned by the positions of the underlying polysilicon and silicon. Silicide layers formed in this manner are often referred to as self-aligned silicide or “salicide.”

In many applications, it is often preferred that the metal layer 10 be formed in an extremely thin film such as 50 A (angstroms), for example. Such thin films can reduce or minimize the consumption of silicon in the silicide formation process and thus facilitate maintaining the integrity of the shallow junctions in the source and drain regions. However, such thin films are often difficult to achieve with a desired degree of uniformity over nonplanar structures such as those shown in FIG. 1. As a consequence, the metal layer 10 may have excessively thin spots, particularly on those areas adjacent vertical structures as indicated at 30 in FIG. 1. These thinner areas may adversely affect the formation of the underlying silicide.

As integrated circuits become more densely packed, the spacing between adjacent vertical structures is shrinking. In addition, the relative height of the vertical structures is growing increasingly tall. As a consequence, the spaces between adjacent gate structures can in effect become deep “holes” 40 as shown in FIG. 3. As the vertical to horizontal aspect ratio of these gate spacing holes between adjacent gates becomes increasingly large, achieving satisfactory coverage of the source and drain regions at the bottoms of such deep holes is made more difficult. As a consequence, the thin spots 30 may become even more problematical.

Semiconductor integrated circuits also utilize metal layers to interconnect various devices. These circuits can include multiple levels of metal layers or “metallizations” to provide electrical connections between large numbers of active semiconductor devices. Advanced integrated circuits, particularly those for microprocessors, may include five or more metallization levels.

A typical metallization level is illustrated in the cross-sectional view of FIG. 4. A lower-level layer 110 includes a conductive feature 112. If the lower-level layer 110 is a lower-level dielectric layer, such as silica or other insulating material, the conductive feature 112 may be a lower-level metallization, and the vertical portion of the upper-level metallization formed in a hole is often referred to as a via since it interconnects two levels of metallization. If the lower-level layer 110 is a silicon layer, the conductive feature 112 may be a doped silicon region, and the vertical portion of the upper-level metallization is often referred to as a contact because it electrically contacts silicon. An upper-level dielectric layer 114 is deposited over the lower-level dielectric layer 110 and the lower-level metallization 112.

A via hole is etched into the upper-level dielectric layer 114 typically using, in the case of silicate dielectrics, a fluorine-based plasma etching process. A preferred technique for metallization, called dual damascene, forms the hole in the dielectric layer 114 into two connected portions, the first being narrow vias through the bottom portion of the dielectric and the second being wider trenches in the surface portion which interconnect the vias.

There are yet other shapes for “holes” including lines and trenches. Also, in dual damascene and similar interconnect structures, as described below, the holes may have a complex shape. In some applications, the hole may not extend through the dielectric layer. The following discussions will often refer to vias and gate spacing holes, but in most circumstances the discussion applies equally well to other types of holes with only a few modifications well known in the art.

A liner layer 116 may be deposited onto the bottom and sides of the hole and above the dielectric layer 114. The liner 116 can perform several functions. It can act as an adhesion layer between the dielectric and the metal since metal films tend to peel from oxides. It can also act as a barrier against inter-diffusion between the oxide-based dielectric and the metal. It may also act as a seed and nucleation layer to promote the uniform adhesion and growth and possibly low-temperature reflow for the deposition of metal filling the hole and to nucleate the even growth of a separate seed layer. One or more liner layers may be deposited, in which one layer may function primarily as a barrier layer and others may function primarily as adhesion, seed or nucleation layers. An interconnect layer 118 of a conductive metal may be deposited over the liner layer 116 to fill the hole and to cover the top of the dielectric layer 114.

Lining or otherwise depositing metal into via holes and similar high aspect-ratio structures such as the gate spacing holes 40 described above, have presented a continuing challenge as their aspect ratios continue to increase. An aspect ratio as used herein is defined as the ratio of the depth of the hole to narrowest width of the hole. In advanced integrated circuits, the via holes may have widths as low as 0.18 μm or even less. The thickness of the dielectric layer 114 is usually at least 0.7 μm, and sometimes twice this, so that the aspect ratio of the hole may be 4:1 or greater. For example, aspect ratios of 6:1 and greater are being proposed.

The deposition of a metal layer by conventional physical vapor deposition (PVD), also called sputtering, is relatively fast. A DC magnetron sputtering reactor has a target which is composed of the metal to be sputter deposited and which is powered by a DC electrical source. The magnetron is scanned about the back of the target and projects its magnetic field into the portion of the reactor adjacent the target to increase the plasma density. The target is typically negatively biased to attract the ions generated in the plasma to sputter the target.

The rate at which material is sputtered from the target may be controlled by controlling the power of the source biasing the target. Because a relatively thin metal deposition is often desired for silicide formation, a low sputtering rate is often desired to facilitate controlling the thickness of the deposition. Consequently, the power level of the target biasing source may be set relatively low to assist in achieving the desired thin layer deposition.

However, conventional DC sputtering (which will be referred to as PVD in contrast to other types of sputtering to be introduced) predominantly sputters neutral atoms. The typical ion densities in PVD are often less than 10⁹ cm⁻³. PVD also tends to sputter atoms into a wide angular distribution, typically having a cosine dependence about the target normal. Such a wide distribution can be disadvantageous for filling a deep and narrow gate spacing hole 40 such as that illustrated in FIG. 3. The large number of off-angle sputter particles can cause a layer 10 to preferentially deposit around the upper corners of the hole 40 and can cause inadequate coverage of the bottom areas 30 of the hole 40 above the silicon region 20.

A recently developed technology of self-ionized plasma (SIP) sputtering allows plasma sputtering reactors to be only slightly modified but to nonetheless achieve efficient lining of metals into high aspect-ratio holes in a low-pressure, low-temperature process. This technology has been described by Fu et al. in U.S. Pat. No. 6,290,825 and by Chiang et al. in U.S. patent application Ser. No. 09/414,614, filed Oct. 8, 1999, both incorporated herein by reference in their entireties. For example, at a sufficiently high plasma density adjacent a target, a sufficiently high density of target metal ions can develop that ionizes additional metal sputtered from the target. As noted above, such a plasma is referred to as a self-ionizing plasma (SIP). The sputtered metal ions may be accelerated across the plasma sheath and toward a biased wafer, thus increasing the directionality of the sputter flux and decreasing scattering of metal particles by the argon. As a result, bottom coverage in deep and narrow holes may be improved. However, to achieve a sufficiently high rate of ionization, the power of the biasing applied to the target may be raised to a level which increases the sputtering rate above that desired to achieve a thin metal layer. SIP sputtering including sustained self-sputtering (SSS), is also described by Fu et al. in U.S. patent application Ser. No. 08/854,008, filed May 8, 1997 and by Fu in U.S. Pat. No. 6,183,614 B1, Ser. No. 09/373,097, filed Aug. 12, 1999.

Ionizing plasmas may also be generated by capacitive coupling. In such chambers, RF energy may be capacitively coupled into the chamber through parallel electrodes such as the wafer pedestal and the target. However, again, the power applied to the target may cause the sputtering rate to rise beyond desirable levels for thin film deposition.

### SUMMARIES OF ILLUSTRATIVE EMBODIMENTS

One embodiment of the present inventions is directed to sputter depositing a metal layer by biasing a sputter target with pulsed power in which the power applied to the target alternates between low and high levels. The high levels are, in one embodiment, sufficiently high to maintain a plasma for ionizing deposition material. The low levels are, in one embodiment, sufficiently low such that the power applied to the target during the high and low levels is, on average, low enough to facilitate deposition of thin layers if desired.

In the illustrated embodiment, the power applied to bias the target is modulated in a plurality of alternating first and second intervals wherein in each of the first intervals, the power level is at a first level sufficiently high to attract ions to sputter the target. In each of the second intervals, the power is applied at a second level higher than the first level and sufficiently high not only to sputter the target but also to maintain a plasma adjacent the target capable of ionizing target material sputtered from said target. Thus, the target is continuously sputtered once deposition onto the wafer is initiated. In the illustrated embodiment the durations of the first intervals of lower power application can be selected to be longer than the durations of the second intervals of higher power application to reduce further the average of the power applied to the target.

Because the power applied during the first intervals is lower than the power applied during the second intervals which alternate with the first intervals, the sputtering rate of the target can be substantially reduced during the first intervals as compared to that of the second intervals. As a consequence, it is believed that the average sputtering rate can be sufficiently low to facilitate deposition of thin layers of metal.

On the other hand, because the power applied during the second intervals is higher than the power applied during the first intervals which alternate with the second intervals, the rate at which target material sputtered from the target is ionized prior to deposition can be significantly increased during the second intervals as compared to that of the first intervals. As a consequence, it is believed that the average ionization rate can be sufficiently high to provide good bottom coverage of deep and narrow holes in CMOS and other structures.

In the illustrated embodiment, a generally planar target coupled with an unbalanced magnetron generate a self-ionizing plasma, particularly when biased at sufficiently high levels of biasing power in the second intervals in which the higher power level is applied to the target. It is appreciated that other types of sputtering targets and magnetrons may be used. For example, hollow cathode targets may be used as well as targets which generate an ionizing plasma by capacitively coupling energy from the target and the workpiece holder into the plasma.

There are additional aspects to the present inventions as discussed below. It should therefore be understood that the preceding is merely a brief summary of some embodiments and aspects of the present inventions. Additional embodiments and aspects of the present inventions are referenced below. It should further be understood that numerous changes to the disclosed embodiments can be made without departing from the spirit or scope of the inventions. The preceding summary therefore is not meant to limit the scope of the inventions. Rather, the scope of the inventions is to be determined only by the appended claims and their equivalents.

### BRIEF DESCRIPTION OF THE DRAWINGS

FIG. 1 is a partial cross-sectional view of a metal layer deposited on CMOS structures of an integrated circuit device, as practiced in the prior art.

FIG. 2 is a partial cross-sectional view of silicide layers formed by the metal layer in the device of FIG. 1, as practiced in the prior art.

FIG. 3 is a partial cross-sectional view of silicide layers formed by a metal layer in a more densely packed CMOS device, as practiced in the prior art.

FIG. 4 is a cross-sectional view of a via filled with a metallization, which also covers the top of the dielectric, as practiced in the prior art.

FIG. 5 is a schematic representation of a sputtering chamber usable with an embodiment of the invention.

FIG. 6 is a schematic representation of electrical interconnections of various components of the sputtering chamber of FIG. 5.

FIG. 7 is a graph depicting a biasing pulse superimposed on a DC component for biasing the target of FIG. 5 in accordance with one embodiment of the present inventions.

FIG. 8 is a partial cross-sectional view of one example of expected silicide layers formed by a metal layer in a more densely packed CMOS device, as practiced in accordance with one aspect of the present inventions.

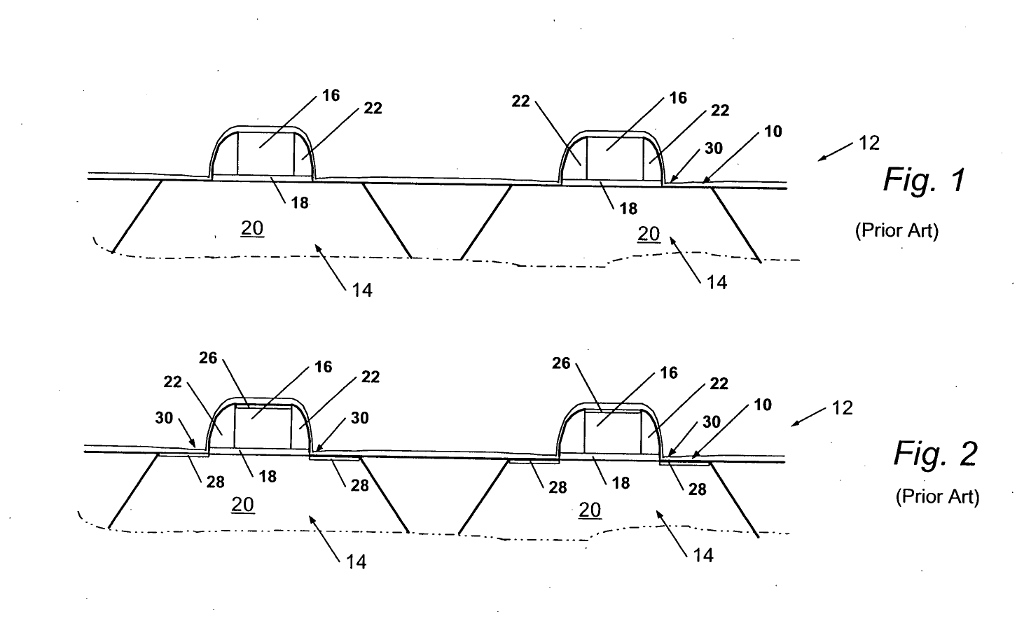

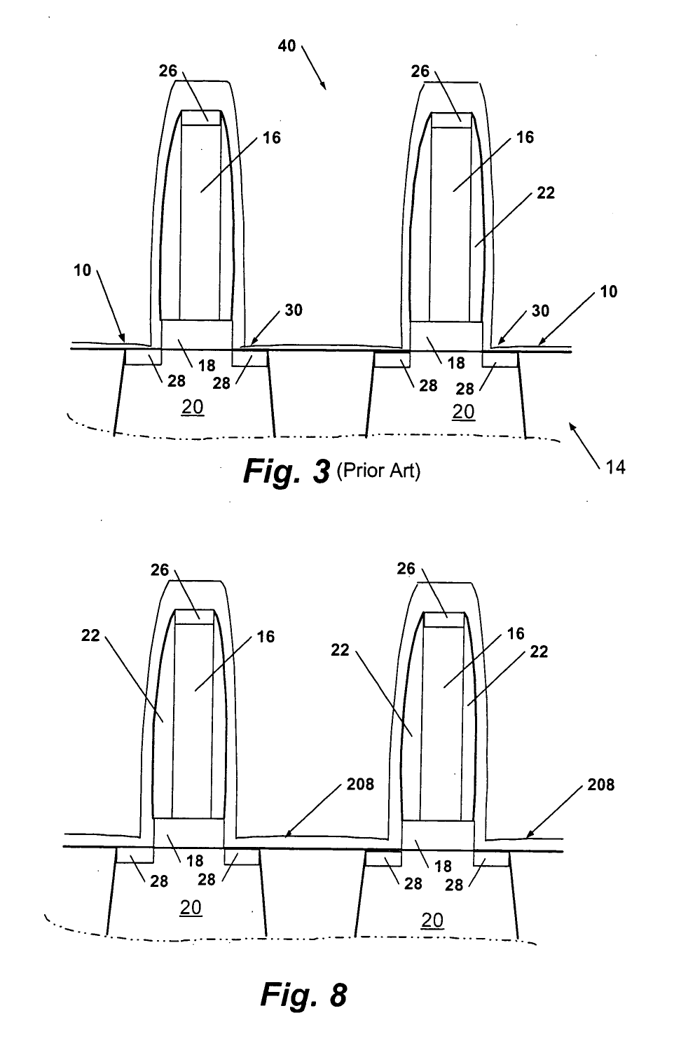

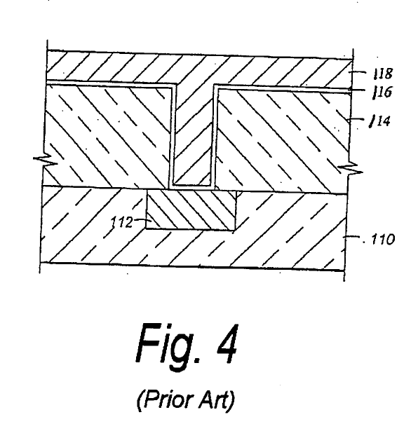

### DESCRIPTIONS OF ILLUSTRATIVE EMBODIMENTS

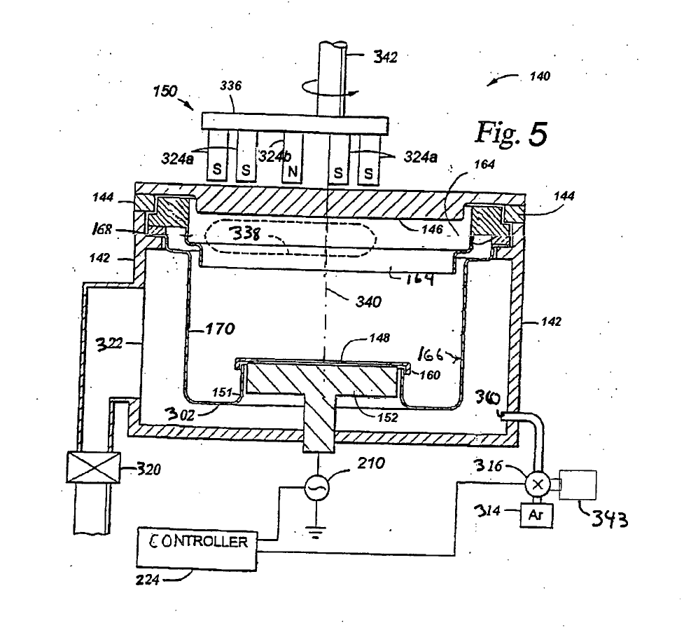

A reactor which is believed capable of providing, for example, both a low average sputtering rate and a sufficiently high deposition material ionization rate for good bottom coverage, is indicated generally at 140 in FIG. 5. The reactor 140 of the illustrated embodiment is a magnetron type reactor based on a modification of the Endura PVD Reactor available from Applied Materials, Inc. of Santa Clara, Calif. The illustrated reactor 140 is capable of self-ionized sputtering (SIP). This SIP mode may be used in one embodiment in which deposition directed to the bottoms of high aspect ratio holes is desired, for example.

The reactor 140 includes a vacuum chamber 142, usually of metal and electrically grounded, sealed through a target isolator 144 to a PVD target 146 having at least a surface portion composed of the material to be sputter deposited on a wafer 148. A magnetron 150 coupled to the target 146 generates a plasma adjacent to the target for sputtering the target and ionizing the sputtered deposition material.

The wafer also referred to as a substrate or workpiece, may be different sizes including 150, 200, 300 and 450 mm. In addition to silicon, the wafer may be composed of glass or other materials. A pedestal electrode 152 has a support surface which supports the wafer and biases the wafer 148 to attract ionized deposition material. A wafer clamp 160 holds the wafer 148 on the pedestal electrode 152. Resistive heaters, refrigerant channels, and a thermal transfer gas cavity in the pedestal 152 can be provided to allow the temperature of the pedestal to be controlled to temperatures of less than −40° C., thereby allowing the wafer temperature to be similarly controlled.

The reactor 140 also biases the target 146. In one aspect of the illustrated embodiments, the power applied to bias the target is modulated in a plurality of alternating first and second intervals wherein in each of the first intervals, the power level is at a first level sufficiently high to attract ions to sputter the target but at a relatively low sputtering rate if desired. In each of the second intervals, the power is applied at a second level higher than the first level and sufficiently high not only to sputter the target but also to maintain a plasma adjacent the target capable of ionizing target material sputtered from said target. The overall sputtering rate will be an average of the sputtering rates in the alternating intervals. As a consequence, the average sputtering rate can be sufficiently low to facilitate thin film deposition and the ionization rate can be sufficiently high to provide good bottom coverage in high aspect ratio holes. In the illustrated embodiment the durations of the first intervals of lower power application can be selected to be longer than the durations of the second intervals of higher power application to reduce further the average of the power applied to the target.

A darkspace shield 164 and a chamber shield 166 separated by a second dielectric shield isolator 168 are held within the chamber 142 to protect the chamber wall 142 from the sputtered material. In one embodiment, the darkspace shield 164 is permitted to float electrically and the chamber shield 166 is electrically grounded. However, in some embodiments, either or both shields may be grounded, floating or biased to the same or different nonground levels. The chamber shield 166 can also act as an anode grounding plane in opposition to the cathode target 146 and the RF pedestal electrode 152, thereby capacitively supporting a plasma. If the darkspace shield is permitted to float electrically, some electrons can deposit on the darkspace shield 164 such that a negative charge builds up there. It is believed that the negative potential could not only repel further electrons from being deposited, but also confine the electrons in the main plasma area, thus reducing the electron loss, sustaining low-pressure sputtering, and increasing the plasma density, if desired. The plasma darkspace shield 164 is generally cylindrically-shaped. The plasma chamber shield 166 is generally bowl-shaped and includes a generally cylindrically shaped, vertically oriented wall 170. It is appreciated that the shields may have other shapes as well.

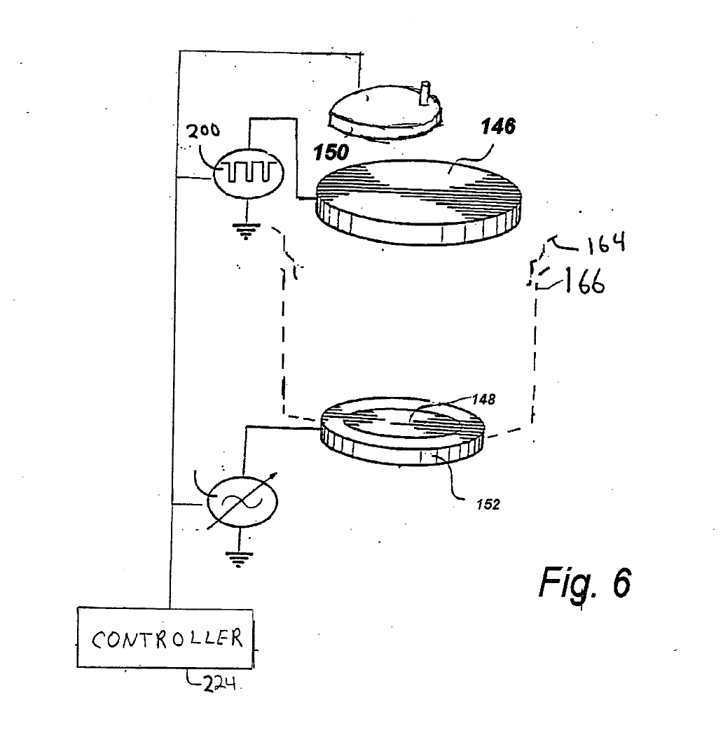

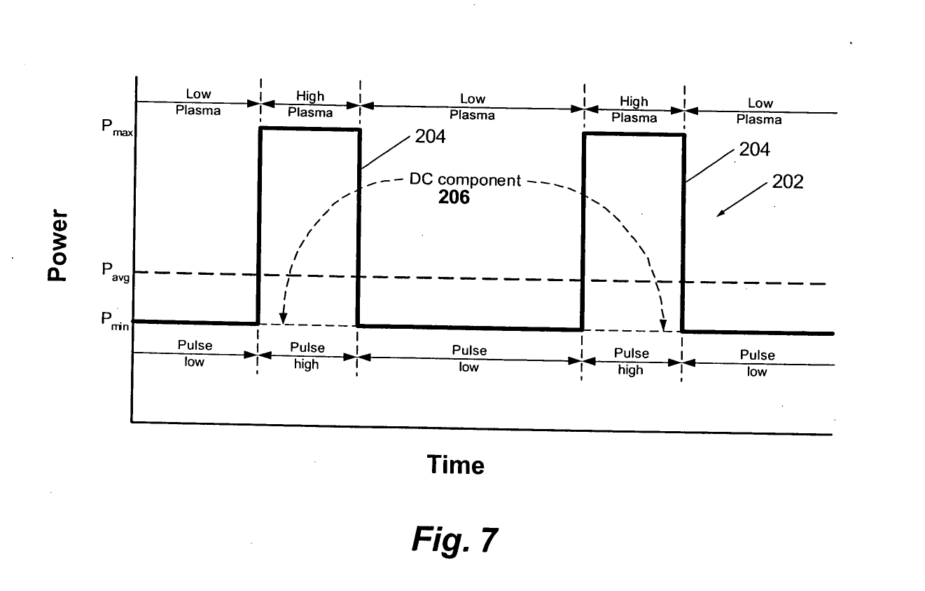

FIG. 6 is a schematic representation of the electrical connections of the plasma generating apparatus of the illustrated embodiment. To attract the ions generated by the plasma to sputter the target 146, and to maintain a plasma for ionizing sputtered deposition material, the target 146 is preferably negatively biased by a pulse type power source 200 to provide an average power of 1-80 kW, for example. A schematic diagram of one example of a suitable power pulse train 202 for biasing the target, is depicted in FIG. 7. The pulse train 202 includes a plurality of pulses 204 superimposed on a DC component 206. The DC component of the source 200 negatively biases the target 146 to about −400 to −600 VDC with respect to the chamber shield 166 to ignite and maintain the plasma. A voltage less than −1000 VDC is generally suitable for many applications. In the illustrated embodiment, the DC component 206 of the pulse train 202 represents the minimum power Pₘᵢₙ of the pulse train. A target power of between 0.1 and 5 kW is typically used to ignite a plasma while a greater power of greater than 10 kW is often preferred for SIP sputtering. In this embodiment, a suitable power range for the minimum power Pₘᵢₙ of the power pulse train 202 is believed to be 0.1 to 5 kW with a range of 100 watts to 1 K watt preferred. This minimum power is applied to negatively bias the target to maintain a plasma and to sputter the target without interruption while the film is deposited in this embodiment.

Superimposed on the DC component is the plurality of pulses 204, each of which alternates between a “pulse low” interval in which the power minimum Pₘᵢₙ as represented by the DC component 206 is applied to the target, and a “pulse high” interval in which a power maximum as represented by Pₘₐₓ is applied to the target. During each “pulse low” interval, the power applied to the target is relatively low. As a consequence, the plasma density adjacent the target, the target sputtering rate and the deposition material ionization rate are all relatively low during each pulse low interval. In the illustrated embodiment, it is preferred that the minimum power Pₘᵢₙ of each pulse low interval remain nonzero such that at least the sputtering rate remains nonzero during the pulse low intervals. It is believed that such an arrangement facilitates plasma stability and uniformity of results from wafer to wafer.

During each “pulse high” interval, power Pₘₐₓ applied to the target is higher. As a consequence, the plasma density adjacent the target, the target sputtering rate and the deposition material ionization rate are higher during each pulse high interval. In the illustrated embodiment, the power level Pₘₐₓ of each pulse high interval is sufficiently high to maintain a self ionizing plasma (SIP) to ionize a significant portion of the material being sputtered from the target during each pulse high period. As a consequence, it is believed that bottom coverage of deep aspect ratio holes may be achieved yet maintaining a sufficiently low average sputtering rate to facilitate thin film depositions. One example of an expected improved coverage is depicted in FIG. 8. As shown therein, the metal layer 208 is depicted as having improved bottom coverage for high aspect ratio holes such as those found between densely packed gates in CMOS devices.

The power level applied during the pulse high intervals will vary, depending upon the particular application. For example, for deposition of cobalt or nickel, it is believed that a power level Pₘₐₓ in the range of 15-25 K watts would be suitable during the pulse high intervals. For deposition of titanium, tantalum or their nitrides, a range of 20-30 K watts is believed to be suitable. For deposition of copper, a range of 30-80 K watts is believed to be suitable.

Although the sputtering rate of the target may rise substantially during each pulse high interval, it is appreciated that the average power P_{avg} applied to the target is lower than the maximum power Pₘₐₓ. Consequently, the average sputtering rate will similarly be lower than the sputtering rate during the pulse high intervals alone. For thin film applications, it is believed that a suitably low average sputtering rate may be achieved by appropriate selections of the high and low power levels, Pₘₐₓ and Pₘᵢₙ, and the durations of the respective pulse low and pulse high intervals. For many such applications, it is believed that providing pulse low intervals longer in duration than pulse high intervals may provide suitable results.

In the illustrated embodiment, deposition of a thin layer may be accomplished in 30 seconds for example. During this 30 second deposition period, the power supply to the target may be pulsed at a frequency of 10 Hz, for example. At this frequency, there would be 10 cycles of alternating pulse high and pulse low intervals during each second of deposition. If so, each cycle of one pulse high interval and one pulse low interval would have a duration of 0.1 seconds. Thus, during a 30 second deposition, the power to the target would be pulsed in 300 cycles. The pulse frequency may vary, depending upon the application. It is believed that a pulse frequency in the range of 1-100 Hz or more preferably 5-20 Hz may be appropriate for a number of applications. Also, the duration of the layer deposition may vary as well. At present, for depositions lasting 10-50 seconds, 10-500 cycles of high and low pulses during the deposition is believed to be appropriate.

Within each cycle, it is generally preferred that the duration of the pulse low interval be longer than that of the pulse high interval in each cycle. The ratio of the duration of the pulse high interval to the duration of the cycle (the duty cycle) may range from ½ to ⅛, for example. Values for the parameters including Pₘₐₓ, Pₘᵢₙ, and the interval durations may be determined empirically. These parameters may be affected by the particular design goals of the application including repeatability of results, the thickness of the deposited layer and the uniformity of the deposited layer. In the illustrated embodiment, an average power P_{avg} in the range of 15-30 kW for material such as Ti is believed to be suitable.

In the illustrated embodiment, the values Pₘₐₓ, Pₘᵢₙ, and the pulse high and pulse low interval durations are depicted as being relatively constant from interval to interval. It is appreciated that these values may vary from interval to interval, and within each interval, depending upon the particular application. Moreover, the voltage or current output of the source 200 may be modulated as appropriate.

A source 210 applies RF power to the pedestal electrode 152 to bias the wafer 148 to attract deposition material ions during SIP sputter deposition. In addition, the source 210 may be configured to apply RF power to the pedestal electrode 152 to couple supplemental energy to the plasma. During SIP deposition, the pedestal 152 and hence the wafer 148 may be left electrically floating, but a negative DC self-bias may nonetheless develop on it. Alternatively, the pedestal 152 may be negatively biased by a source at a negative voltage of −30 VDC, for example, to negatively bias the wafer 148 to attract the ionized deposition material to the substrate.

If the source 210 biasing the wafer through the pedestal is an RF power supply, the supply may operate at a frequency of 13.56 MHz, for example. Other frequencies are suitable such as 60 MHz, depending upon the particular application. The pedestal 152 may be supplied with RF power in a range of 10 watts to 5 kW, for example, a more preferred range being 150 to 300 W for a 200 mm wafer in SIP deposition.

The above-mentioned power and voltage levels and frequencies may vary of course, depending upon the particular application. A computer-based controller 224 may be programmed to control the power levels, voltages, currents and frequencies of the various sources in accordance with the particular application.

Retuming to the large view of FIG. 5, the lower cylindrical portion 170 of the chamber shield 166 continues downwardly to well below the top of the pedestal 152. The chamber shield 166 then continues radially inward in a bowl portion 302 and vertically upward in an innermost cylindrical portion 151 to approximately the elevation of the wafer 148 but spaced radially outside of the pedestal 152.

The shields 164, 166 are typically composed of stainless steel, and their inner sides may be bead-blasted or otherwise roughened to promote adhesion of the material sputter deposited on them. At some point during prolonged sputtering, however, the deposited material builds up to a thickness that is likely to flake off, producing deleterious particles. Before this point is reached, the shields 164, 166 should be cleaned or replaced. However, the more expensive isolators 144, 168 do not need to be replaced in most maintenance cycles. Thus, the maintenance cycle is determined by flaking of the shields.

As mentioned, the darkspace shield 164, if floating can accumulate some electron charge and build up a negative potential. Thus biased, it repels further electron loss to the darkspace shield 164 and confines the plasma nearer the target 146. Ding et al. have disclosed a similar effect with a somewhat similar structure in U.S. Pat. No. 5,736,021. In selecting an appropriate darkspace shield, it is noted that the darkspace shield 164 electrically shields the chamber shield 166 from the target 146 so that it should not extend too far away from the target 146. If it is too long, it is believed it can become more difficult to strike the plasma; but, if it is too short, it is believed that electron loss can increase such that sustaining the plasma at lower pressure is more difficult and the plasma density may fall. In the illustrated embodiment, the shield 164 has an axial length of 7.6 cm but may range from 6-10 cm in a preferred embodiment.

Referring again to FIG. 5, a gas source 314 supplies a sputtering working gas, typically the chemically inactive noble gas argon, to the chamber 142 through a mass flow controller 316. The working gas can be admitted to the top of the chamber or, as illustrated, at its bottom, either with one or more inlet pipes penetrating apertures through the bottom of the shield chamber shield 166 or through a gap between the chamber shield 166, the wafer clamp 160, and the pedestal 152. A vacuum pump system 320 connected to the chamber 142 through a wide pumping port 322 maintains the chamber at a low pressure. Although the base pressure can be held to about 10⁻⁷ Torr or even lower, the pressure of the working gas is typically maintained between about 1 and 1000 milliTorr in conventional sputtering and below about 5 milliTorr in SIP sputtering. The computer-based controller 224 controls the reactor including the DC target power supply 200.

To provide efficient sputtering, the magnetron 150 is positioned in back of the target 146. It has opposed magnets 324a, 324b connected and supported by a magnetic yoke 336. The magnets create a magnetic field adjacent the magnetron 150 within the chamber 142. The magnetic field traps electrons and, for charge neutrality, the ion density also increases to form a high-density plasma region 338. The magnetron 150 is usually rotated about the center axis 340 of the target 146 by a motor-driven shaft 342 to achieve full coverage in sputtering of the target 146. To achieve a high-density plasma 338 of sufficient ionization density to allow self-ionization, the power density delivered to the area adjacent the magnetron 150 is preferably made high during the pulse high intervals. It is believed that this may be achieved by increasing the power level delivered from the power supply 200 during the pulse high intervals and by reducing the area of magnetron 150, for example, in the shape of a triangle or a racetrack. A 60-degree triangular magnetron, which is rotated with its tip approximately coincident with the target center 340, covers only about ⅙ of the target at any time. Coverage of ¼ is the preferred maximum in a commercial reactor capable of SIP sputtering.

To decrease the electron loss, the inner magnetic pole represented by the inner magnet 324b and magnetic pole face should have no significant apertures and be surrounded by a continuous outer magnetic pole represented by the outer magnets 324a and pole face. Furthermore, to guide the ionized sputter particles to the wafer 148, the outer pole should produce a much higher magnetic flux than the inner pole. The extending magnetic field lines trap electrons and thus extend the plasma closer to the wafer 148. The ratio of magnetic fluxes should be at least 150% and preferably greater than 200%. Two embodiments of Fu's triangular magnetron have 25 outer magnets and 6 or 10 inner magnets of the same strength but opposite polarity.

When the argon is admitted into the chamber, the DC voltage difference between the target 146 and the chamber shield 166 ignites the argon into a plasma, and the positively charged argon ions are attracted to the negatively charged target 146. The ions strike the target 146 at a substantial energy and cause target atoms or atomic clusters to be sputtered from the target 146. Some of the target particles strike the wafer 148 and are thereby deposited on it, thereby forming a film of the target material. In reactive sputtering of a metallic nitride, nitrogen is additionally admitted into the chamber from a source 343, and it reacts with the sputtered metallic atoms to form a metallic nitride on the wafer 148.

In operation, a gate valve operatively coupled to the exhaust outlet 322 is fully opened in order to achieve the desired vacuum level of about 1×10⁻⁸ Torr in the deposition chamber 142 prior to introduction of the process gas(es) into the chamber. To commence processing within the sputtering chamber 142, argon or other process gasses are flowed into the sputtering chamber 142 via a gas inlet 360. After the gas stabilizes at a pressure of about 0.1-40 milliTorr (preferably 1-5 milliTorr), power is applied to the target 146 via the power supply 200. The gas mixture continues to flow into the sputtering chamber 142 via the gas inlet 360 and is pumped therefrom via the pump 320 to maintain gas pressure in the chamber. The power applied to the target 146 causes the gas to form an SIP plasma and to generate ions such as argon ions which are attracted to and strike the target 146, causing target material (e.g., cobalt or nickel) to be ejected therefrom. The ejected target material travels to and deposits on the wafer 148 supported by the pedestal 152. In accordance with the SIP process, the plasma created by the unbalanced magnetron ionizes a portion of the sputtered target material. By adjusting the RF power signal applied to the substrate support pedestal 152, a negative bias can be created between the substrate support pedestal 152 and the plasma. The negative bias between the substrate support pedestal 152 and the plasma causes target material ions and argon ions to accelerate toward the pedestal 152 and any wafer supported thereon. Accordingly, both neutral and ionized target material may be deposited on the wafer, providing good sidewall and upper sidewall coverage in accordance with SIP sputtering. In addition, particularly if sufficient RF power is optionally applied to the pedestal the wafer may be sputter-etched by the argon ions at the same time the material from the target 146 deposits on the wafer (i.e., simultaneous deposition/sputter-etching).

In one embodiment, the chamber 142 may be capable of self-ionized sputtering including sustained self-sputtering (SSS). In this case, after the plasma has been ignited, the supply of argon may be cut off in the case of SSS, and the metal ions may have sufficiently high density to resputter the target with a yield of greater than unity. Alternatively, some argon may continue to be supplied, but at a reduced flow rate and chamber pressure and perhaps with insufficient target power density to support pure sustained self-sputtering but nonetheless with a significant but reduced fraction of self-sputtering. It is believed that if the argon pressure is increased to significantly above 5 milliTorr, the argon will remove energy from the metal ions, thus decreasing the self-sputtering. The wafer bias attracts the ionized fraction of the metal particle deep into the hole.

To achieve deeper hole coating with a partially neutral flux, it may be desirable to increase the distance between the target 146 and the wafer 148, that is, to operate in a long-throw mode. In previously practiced long-throw, the target-to-substrate spacing is typically greater than half the substrate diameter, or greater than 100% wafer diameter, or at least 80% of the substrate diameter, or at least 90% of the substrate diameter, or at least 140% of the substrate diameter. The throws mentioned in the examples of the present embodiment are referenced to 200 mm wafers. For many applications, it is believed that a target to wafer spacing of 50 to 1000 mm will be appropriate. Long-throw in conventional sputtering reduces the sputtering deposition rate, but ionized sputter particles typically do not suffer a large decrease.

Many of the features of the apparatus and process of the inventions can be applied to sputtering not involving long throw. Although it is believed that the inventions are particularly useful at the present time for silicide layer formation, the different aspects of the invention may be applied to sputtering other materials and for other purposes.

It will, of course, be understood that modifications of the present invention, in its various aspects, will be apparent to those skilled in the art, some being apparent only after study, others being matters of routine mechanical and process design. Other embodiments are also possible, their specific designs depending upon the particular application. As such, the scope of the invention should not be limited by the particular embodiments herein described but should be defined only by the appended claims and equivalents thereof.

1. A method of biasing a target in a sputter deposition chamber for depositing a layer of material on a workpiece, comprising:
applying power continuously to said target at a negative voltage; and
modulating said power in a plurality of alternating first and second intervals while depositing target material on said workpiece, wherein in each of said first intervals, said power level is at a first level sufficiently high to maintain a plasma adjacent said target to sputter said target and wherein in each of said second intervals, said power is at a second level higher than said first level and sufficiently high to maintain a plasma adjacent said target to sputter said target and to ionize target material sputtered from said target and wherein said first intervals are longer in duration than said second intervals.

2. A method of biasing a target in a sputter deposition chamber, comprising:
applying power continuously to said target while depositing target material on said workpiece, wherein said power includes a negative voltage DC component having a magnitude greater than zero and sufficiently large to maintain a plasma adjacent said target and a negative voltage pulsed component superimposed on said DC component wherein said pulsed component has a frequency of 1-100 Hz.

3. The method of claim 2 wherein said pulsed component has a frequency of at least 5 Hz.

4. The method of claim 3 wherein said pulsed component has a frequency no greater than 20 Hz.

5. The method of claim 2 wherein said power DC component is at least 0.1 K watts.

6. The method of claim 2 wherein the average of said power applied to said target while depositing target material on said workpiece is in the range of 10-80 K watts.

7. The method of claim 2 wherein said pulsed component has a frequency of 5-20 Hz.

8. The method of claim 2 wherein said pulsed component has 500 cycles or less while target material is deposited on said workpiece.

9. A method of sputtering a target in a sputter deposition chamber, comprising:
sputtering said target continuously in a plurality of alternating first and second intervals at a frequency in the range of 1-100 Hz, wherein in each of said first intervals, said target is sputtered at a first nonzero rate and wherein in each of said second intervals, said target is sputtered at a second rate higher than said first rate target; and
ionizing material sputtered from said target in said plurality of second intervals in a self-ionizing plasma adjacent said target.

10. The method of claim 9 wherein said sputtering and ionizing includes rotating a magnetron about the back of said target in the chamber, said magnetron having an area of no more than about ¼ of the area of the target and including an inner magnetic pole of one magnetic polarity surrounded by an outer magnetic pole of an opposite magnetic polarity, a magnetic flux of said outer pole being at least 50% larger than the magnetic flux of said inner pole.

11. The method of claim 9 wherein said first intervals are longer in duration than said second intervals;

12. A method of sputtering a target in a sputter deposition chamber for depositing a layer of sputtered material on a workpiece, comprising:
generating a plasma adjacent said target in a plurality of alternating first and second intervals at a frequency in the range of 1-100 Hz, wherein in each of said second intervals levels, said plasma includes a self-ionizing plasma which ionizes at least a portion of said sputtered material.

13. The method of claim 12 wherein said first intervals are longer in duration than said second intervals.

14. A method of forming a silicide layer in a CMOS workpiece, comprising:
continuously sputtering a target in a sputter deposition chamber in a plurality of alternating first and second intervals at a frequency in the range of 1-100 Hz to deposit a layer of metal on silicon in said workpiece, wherein in each of said first intervals, said target is sputtered at a first nonzero rate and wherein in each of said second intervals, said target is sputtered at a second rate higher than said first rate target;
ionizing material sputtered from said target in said plurality of second intervals in a self-ionizing plasma adjacent said target prior to being deposited in said metal layer; and
heating at least a portion of said metal layer to form a silicide in said workpiece.

15. An apparatus for biasing a target in a chamber for depositing a layer of sputtered material on a workpiece, comprising:
a controllable power source adapted to bias said target to sputter said target and to maintain a plasma adjacent said target; and
a controller adapted to control said power source to apply power continuously to said target to bias said target at a negative voltage; and to modulate said power in a plurality of alternating first and second intervals while target material is deposited on said workpiece, wherein in each of said first intervals, said power level is at a first level sufficiently high to maintain a plasma adjacent said target to sputter said target and wherein in each of said second intervals, said power is at a second level higher than said first level and sufficiently high to maintain a plasma adjacent said target to sputter said target and to ionize target material sputtered from said target.

16. An apparatus for depositing a layer of sputtered material on a workpiece, comprising:
a chamber;
a target having a sputterable surface within said chamber;
a magnetron positioned adjacent said sputterable surface and adapted to project a magnetic field for a self-ionizing plasma adjacent said sputterable surface;
a controllable power source adapted to bias said target to sputter said target and to maintain a plasma adjacent said target; and
a controller adapted to control said power source to apply power continuously to said target to bias said target at a negative voltage; and to modulate said power in a plurality of alternating first and second intervals while target material is deposited on said workpiece, wherein in each of said first intervals, said power level is at a first level sufficiently high to maintain a plasma adjacent said target to sputter said target and wherein in each of said second intervals, said power is at a second level higher than said first level and sufficiently high to maintain a plasma adjacent said target to sputter said target and to ionize target material sputtered from said target.

17. The apparatus of claim 16 wherein said magnetron has an area of no more than about ¼ of the area of the target and including an inner magnetic pole of one magnetic polarity surrounded by an outer magnetic pole of an opposite magnetic polarity, the magnetic flux of said outer pole being at least 50% larger than the magnetic flux of said inner pole.

18. An apparatus for biasing a target in a chamber for depositing a layer of sputtered material on a workpiece, comprising:
means for applying power continuously to said target while target material is deposited on said workpiece, wherein said power includes a negative voltage DC component having a magnitude greater than zero and sufficiently large to maintain a plasma adjacent said target and a negative voltage pulsed component superimposed on said DC component wherein said pulsed component has a frequency of 1-100 Hz.
